(19) United States
(12) Patent Application Publication
(10) Pub. No.: US 2008/0265377 A1
(43) Pub. Date: Oct. 30, 2008

(54) AIR GAP WITH SELECTIVE PINCHOFF USING AN ANTI-NUCLEATION LAYER

(75) Inventors: Lawrence A. Clevenger, LaGrangeville, NY (US); Matthew E. Colburn, Hopewell Junction, NY (US); Daniel C. Edelstein, White Plains, NY (US); Shom Ponoth, Guilderland, NY (US); Gregory Breyta, San Jose, CA (US)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignee: INTERNATIONAL BUSINESS MACHINES CORPORATION, Armonk, NY (US)

(21) Appl. No.: 11/741,908

(22) Filed: Apr. 30, 2007

(51) Int. Cl. H01L 21/311; H01L 29/06

(52) U.S. Cl. 257/618; 438/702; 257/E21.249; 257/E29.005

(57) ABSTRACT

A method of forming cavities within a semiconductor device is disclosed. The method comprises depositing an anti-nucleating layer on the interior surface of cavities within an ILD layer of the semiconductor device. This anti-nucleating layer prevents subsequently deposited dielectric layers from forming within the cavities. By preventing the formation of these layers, the capacitance is reduced, thereby resulting in improved semiconductor performance.

### FIELD OF THE INVENTION

The present invention relates generally to semiconductor device processing and, more particularly to interconnect structures having air gaps between adjacent conductive lines.

### BACKGROUND

The evolution of integrated circuits toward higher complexity and decreased size has lead to closer spacing between the conducting wires (lines). Resulting capacitance increase produces time delays and creates cross-talk between the wiring elements. Current semiconductor fabrication techniques typically comprise many conductive wiring levels to complete the final working integrated circuits.

Semiconductor devices are typically joined together to form useful circuits using what is called “interconnect structures.” These interconnect structures are typically made of conductors such as copper or aluminum and dielectric materials such as silicon dioxide. The speed of these interconnects can be roughly assumed to be inversely proportional to the product of the line resistance, and the capacitance between lines. To reduce the delay and increase the speed, it is desirable to reduce the capacitance. The use of air gaps to decrease these capacitance losses is known in the art. Note that while the term “air gap” or “air cavity” is commonly used in the industry, in actuality these gaps are really “vacuum cavities,” similar in concept to a light bulb.

U.S. Pat. No. 7,041,571 to Strane, which is incorporated herein by reference, discloses the use of air gaps in this manner. However, there is still room for improvement in the use of air gaps. In current implementations, inter-level dielectric (ILD) material may partially adhere to the air gap sidewalls during the air gap sealing process, increasing the capacitance, and thereby reduce performance of the semiconductor device. Therefore, what is needed is an improved method for implementing air gaps in semiconductor devices.

### SUMMARY OF THE INVENTION

The present invention provides a method of forming cavities within a semiconductor device comprising the steps of:
forming an open cavity within a first dielectric layer of the semiconductor device, with the first dielectric layer having an oxide layer disposed thereon, and the oxide layer having a top surface, and the open cavity having an interior surface;
depositing an anti-nucleating layer on the oxide layer, whereby the anti-nucleating layer adheres to the interior surface of the open cavity;
removing the anti-nucleating layer from the top surface of the first dielectric layer, whereby the anti-nucleating layer remains on the interior surface of the open cavity; and
depositing a second dielectric layer on the semiconductor device, whereby a sealed cavity is formed.

Still further, according to the present invention, in the aforementioned method, the step of depositing an anti-nucleating layer comprises depositing a diamond-like carbon (DLC) layer.

Still further, according to the present invention, in the aforementioned method, the step of depositing the DLC layer comprises depositing a DLC layer having a thickness in the range of about 1 nanometer to about 20 nanometers.

Still further, according to the present invention, in the aforementioned method, the step of removing said anti-nucleating layer from the top surface of the oxide layer, is performed with a sputter deposition tool.

Still further, according to the present invention, in the aforementioned method, the step of depositing an anti-nucleating layer on the oxide layer is performed with a spin coat technique.

Still further, according to the present invention, in the aforementioned method, the step of depositing an anti-nucleating layer on the oxide layer is performed with chemical solution deposition.

Still further, according to the present invention, in the aforementioned method, the step of depositing an anti-nucleating layer on the oxide layer is performed with chemical vapor deposition.

Still further, according to the present invention, in the aforementioned method, the step of depositing an anti-nucleating layer on the oxide layer is performed with plasma enhanced chemical vapor deposition.

Still further, according to the present invention, in the aforementioned method, the step of removing the anti-nucleating layer from the top surface of the oxide layer is performed with a plasma etch process.

Still further, according to the present invention, in the aforementioned method, the step of removing the anti-nucleating layer from the top surface of the oxide layer is performed with a reactive ion etch process.

Still further, according to the present invention, in the aforementioned method, the step of removing the anti-nucleating layer from the top surface of the oxide layer is performed with an ion beam milling process.

Still further, according to the present invention, in the aforementioned method, the step of depositing a second dielectric layer on the semiconductor device comprises the step of depositing a dielectric selected from the group consisting of SiO2, SiOF, SiCOH, SiC, and SiCN, and porous versions thereof.

Still further, according to the present invention, in the aforementioned method, the step of depositing an anti-nucleating layer comprises depositing an anti-nucleating layer selected from the group consisting of SiO2, SiOF, SiCOH, SiC, and SiCN.

Still further, according to the present invention, in the aforementioned method, the step of depositing an anti-nucleating layer comprises depositing an anti-nucleating layer selected from the group consisting of GeO2, GeC, and GeCN.

Still further, according to the present invention, a semiconductor device is provided, comprising:
a first dielectric layer that comprises a plurality of air cavities disposed thereon, each of the plurality of air cavities having an interior surface;
each of the plurality of air cavities comprising an anti-nucleating layer disposed on the interior surface of the air cavities; and
a second dielectric layer disposed above the first dielectric layer, whereby each of the air cavities is sealed.

Still further, according to the present invention, in the aforementioned device, the anti-nucleating layer is comprised of DLC.

Still further, according to the present invention, in the aforementioned device, the anti-nucleating layer comprised of a member selected from the group consisting of GeO2, GeC, and GeCN.

Still further, according to the present invention, in the aforementioned device, the anti-nucleating layer is comprised of a member selected from the group consisting of SiO2, SiOF, SiCOH, SiC, and SiCN.

Still further, according to the present invention, in the aforementioned device, the anti-nucleating layer has a thickness in the range of about 1 nm to about 20 nm.

### BRIEF DESCRIPTION OF THE DRAWINGS

The structure, operation, and advantages of the present invention will become further apparent upon consideration of the following description taken in conjunction with the accompanying figures (FIGs.). The figures are intended to be illustrative, not limiting.

Certain elements in some of the figures may be omitted, or illustrated not-to-scale, for illustrative clarity. The cross-sectional views may be in the form of “slices”, or “near-sighted” cross-sectional views, omitting certain background lines which would otherwise be visible in a “true” cross-sectional view, for illustrative clarity. Block diagrams may not illustrate certain connections that are not critical to the implementation or operation of the present invention, for illustrative clarity.

In the drawings accompanying the description that follows, often both reference numerals and legends (labels, text descriptions) may be used to identify elements. If legends are provided, they are intended merely as an aid to the reader, and should not in any way be interpreted as limiting.

Often, similar elements may be referred to by similar numbers in various figures (FIGs) of the drawing, in which case typically the last two significant digits may be the same, the most significant digit being the number of the drawing figure (FIG).

FIGS. 1 and 2 illustrate a prior art air gap formation process.

FIGS. 3-5 illustrate an embodiment of air gap formation in accordance with the present invention.

FIG. 6 shows a flowchart of process steps for carrying out the method of the present invention.

### DETAILED DESCRIPTION

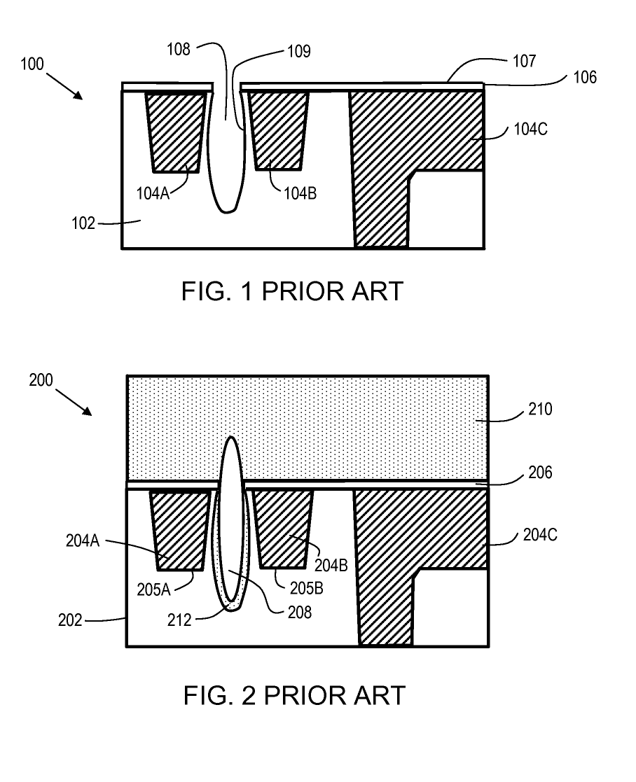

For the purposes of providing context in which to explain the present invention, relevant parts of the prior art process will be briefly discussed. Referring now to FIG. 1 a cross sectional view of a portion of a prior art semiconductor device 100 is shown. Within a first ILD layer 102 a plurality of metal areas 104A, 104B, and 104C are shown. The metal areas can be interconnect lines (e.g. 104A and 104B), or vias, as is the case with 104C. On top of first ILD layer 102 is an oxide layer 106 having a top surface 107. In the example illustrated in FIG. 1, it is desired to form an air gap between interconnect 104A and interconnect 104B. The process steps leading up to the semiconductor device 100 of FIG. 1 include performing an etch (such as a Reactive Ion Etch (RIE)), and employing a post-etch cleaning process, to form open cavity 108 having interior surface 109.

FIG. 2 shows a cross sectional view of a portion of a prior art semiconductor device 200 after a subsequent step is performed on semiconductor device 100, using the prior art process for forming an air gap. In this step, a second dielectric layer 210 is deposited onto oxide layer 206. Second dielectric layer 210 could be any typical IC chip insulating film deposited by plasma enhanced chemical vapor deposition (PECVD) or CVD, such as for example, SiO2, SiOF, SiCOH, SiC, SiCN, or porous versions of these. As an example of a Cu/low-k (dielectrics with k<4.0) multilevel wiring technology, second dielectric layer 210 could be PECVD SiCOH. As mentioned previously, like numbers indicate similar features, and oxide layer 206 of FIG. 2 is similar to oxide layer 106 of FIG. 1. The second dielectric layer 210 forms a sealed air cavity 208, in between interconnects 204A and 204B. During the process of depositing second dielectric layer 210, some of the second dielectric layer material (indicated as 212) is deposited on the interior of cavity 208. This has the adverse effect of increasing capacitance. It is therefore desirable to form a sealed air cavity without depositing dielectric material within the air cavity. The preferred dimensions of the air cavity 208 depend on the interconnect heights and spacing that is used. In modern CMOS wiring, the dimensions of the depth and the width of the cavity can range anywhere from about 50 nm (nanometers) up to about 1 um (1000 nm). It's most preferable that the depth of cavity 208 exceeds the depth of the interconnect trench bottoms (indicated as 205A and 205B) by an amount approximately 8% to about 12% preferably about 10% of the depth of the trenches (204A and 204B), so the electric fringing fields are largely contained within the cavity rather than in the remaining dielectric. This is efficiently accomplished by the present invention, which will be described in detail in the following paragraphs.

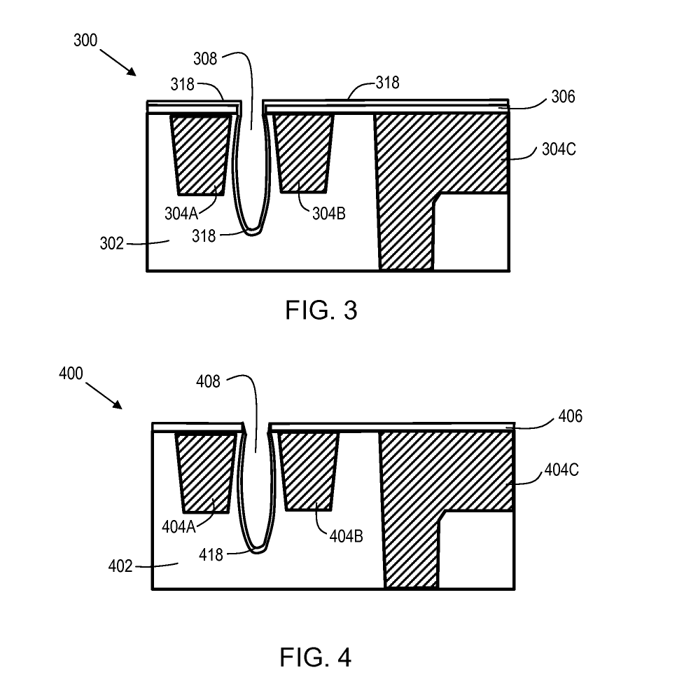

FIG. 3 shows a cross sectional view of a portion of a semiconductor device 300 after a subsequent step is performed on semiconductor device 100, for forming an air gap in accordance with the present invention. In this step, an anti-nucleating layer 318 is deposited onto oxide layer 306. Anti-nucleating layer 318 also lines the interior of cavity 308. Anti-nucleating agents—agents which prevent seed crystal growth, provide for selectivity in subsequent deposition steps. This is discussed during the description of upcoming figures. The anti-nucleation layer 318 is deposited using well known processes including a spin coat technique, chemical solution deposition, or chemical vapor deposition.

In one embodiment, the anti-nucleating layer 318 is comprised of diamond-like carbon (DLC). This material is hydrogenated carbon which is relatively hard and durable, and also serves as a “non-stick” film. Typical thickness values for the DLC layer range from 1 nm to 20 nm. In addition to DLC, other anti-nucleating materials are contemplated, including, but not limited to, amorphous carbon (α-C), or an inorganic dielectric such as a spin-on or PECVD deposited film selected from the group consisting of SiO2, SiOF, SiCOH, SiC, and SiCN. The use of germanium based compounds such as GeO2, GeC, and GeCN is also contemplated.

The anti-nucleating layer 318 of DLC (or amorphous carbon (α-C)) can be applied by various deposition processes such as chemical vapor deposition (CVD), plasma vapor deposition (PVD), sputtering, and the like. The DLC layer 318 has properties similar to the diamond layer, but is less than 100% diamond. Thus, the DLC layer 318 can have other elements incorporated therein such as silicon or germanium.

FIG. 4 shows a cross sectional view of a portion of a semiconductor device 400 after a subsequent step is performed on semiconductor device 300, for forming an air gap in accordance with the present invention. As mentioned previously, the anti-nucleating layer 418 (compare 318) serves as a “non-stick” film. Subsequent deposition of dielectric will not adhere to the anti-nucleating layer 418. It is desirable to have the subsequent dielectric adhere to oxide layer 406. Therefore, the anti-nucleating layer is removed from the surface of oxide layer 406. However, the anti-nucleating layer 418 still remains on the interior surface of cavity 408 (compare to layer 318 of FIG. 3). In one embodiment, the anti-nucleating layer is removed from the top surface of oxide layer 406 via a sputter deposition tool. A variety of other techniques may be used for removing the anti-nucleating layer 418. These techniques include an anisotropic etch process such as plasma etching, reactive ion etching (RIE), sputter-cleaning, or ion beam milling. Process tools for performing the removal of the anti-nucleating layer include RIE etchers, PVD metal tools (which contain sputter preclean chambers), plasma etchers and ashers, and ion beam mills.

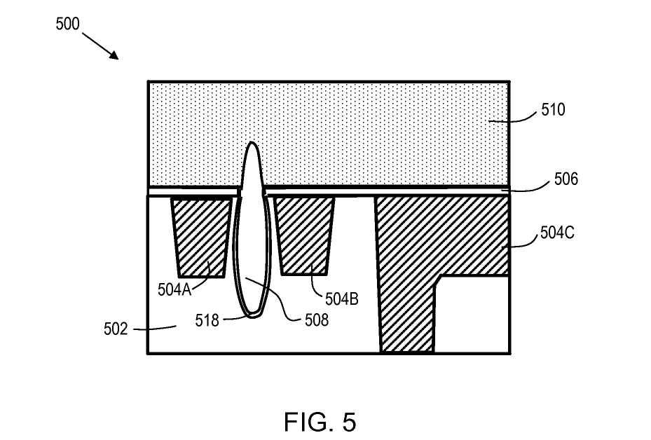

FIG. 5 shows a cross sectional view of a portion of a semiconductor device 500 after a subsequent step is performed on semiconductor device 400, for forming an air gap in accordance with the present invention. In this step, a second dielectric layer 510 is deposited onto oxide layer 506. Because anti-nucleating layer 518 remains on the interior surface of a sealed air cavity 508, dielectric material does not adhere to the interior surface of cavity 508. Therefore, the capacitance of the air gap is lower than that of the prior art method described previously. Depending on the type of dielectric used, a reduction in capacitance of about 5% to 20% has been attributed to the use of the anti-nucleation layer 518.

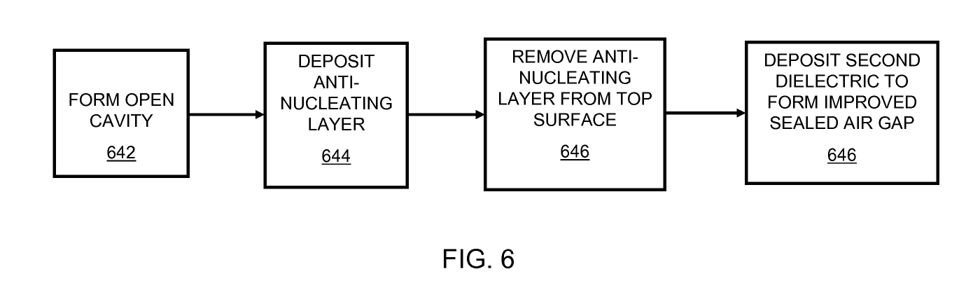

FIG. 6 shows a flowchart of process steps for carrying out the method of the present invention. In process step 642, an open cavity is formed, such as 108 in FIG. 1. In process step 644, an anti-nucleating layer is deposited, such as 318 in FIG. 3. In step 646, the anti-nucleating layer 318 is removed from the top surface, as shown in FIG. 4 (compare with FIG. 3). Finally, in step 646, the second dielectric layer is deposited, such as layer 510 in FIG. 5.

This process may be repeated as necessary for the various layers within a multi-layer semiconductor device. By reducing the capacitance between interconnects, the present invention provides for improved semiconductor performance.

It will be understood that the present invention may have various other embodiments. Furthermore, while the form of the invention herein shown and described constitutes a preferred embodiment of the invention, it is not intended to illustrate all possible forms thereof. It will also be understood that the words used are words of description rather than limitation, and that various changes may be made without departing from the spirit and scope of the invention disclosed. Thus, the scope of the invention should be determined by the appended claims and their legal equivalents, rather than solely by the examples given.

What is claimed is:

1. A method of forming cavities within a semiconductor device comprising the steps of:
forming an open cavity within a first dielectric layer of the semiconductor device, said first dielectric layer having an oxide layer disposed thereon, said oxide layer having a top surface, and said open cavity having an interior surface;
depositing an anti-nucleating layer on the oxide layer, whereby said anti-nucleating layer adheres to the interior surface of said open cavity;
removing said anti-nucleating layer from the top surface of the first dielectric layer, whereby said anti-nucleating layer remains on the interior surface of said open cavity; and
depositing a second dielectric layer on the semiconductor device, whereby a sealed cavity is formed.

2. The method of claim 1, wherein the step of depositing an anti-nucleating layer comprises depositing a DLC layer.

3. The method of claim 2, wherein the step of depositing the DLC layer comprises depositing a DLC layer having a thickness in the range of about 10 to about 200 angstroms.

4. The method of claim 1, wherein the step of removing said anti-nucleating layer from the top surface of the oxide layer, is performed with a sputter deposition tool.

5. The method of claim 1, wherein the step of depositing an anti-nucleating layer on the oxide layer is performed with a spin coat technique.

6. The method of claim 1, wherein the step of depositing an anti-nucleating layer on the oxide layer is performed with chemical solution deposition.

7. The method of claim 1, wherein the step of depositing an anti-nucleating layer on the oxide layer is performed with chemical vapor deposition.

8. The method of claim 1, wherein the step of depositing an anti-nucleating layer on the oxide layer is performed with plasma enhanced chemical vapor deposition.

9. The method of claim 1, wherein the step of removing said anti-nucleating layer from the top surface of the oxide layer is performed with a plasma etch process.

10. The method of claim 1, wherein the step of removing said anti-nucleating layer from the top surface of the oxide layer is performed with a reactive ion etch process.

11. The method of claim 1, wherein the step of removing said anti-nucleating layer from the top surface of the oxide layer is performed with an ion beam milling process.

12. The method of claim 1, wherein the step of depositing a second dielectric layer on the semiconductor device comprises the step of depositing a dielectric selected from the group consisting of SiO2, SiOF, SiCOH, SiC, and SiCN, and porous versions thereof.

13. The method of claim 1, wherein the step of depositing an anti-nucleating layer comprises depositing an anti-nucleating layer selected from the group consisting of SiO2, SiOF, SiCOH, SiC, and SiCN.

14. The method of claim 1, wherein the step of depositing an anti-nucleating layer comprises depositing an anti-nucleating layer selected from the group consisting of GeO2, GeC, and GeCN.

15. The method of claim 1, wherein the step of depositing an anti-nucleating layer comprises depositing a layer of amorphous carbon.

16. A semiconductor device comprising:
a first dielectric layer, said first dielectric layer comprising a plurality of cavities disposed thereon, each of said plurality of cavities having an interior surface;
each of said plurality of cavities comprising an anti-nucleating layer disposed on the interior surface of the cavities; and
a second dielectric layer disposed above the first dielectric layer, whereby each of the cavities is sealed.

17. The semiconductor device of claim 16, wherein the anti-nucleating layer is comprised of DLC.

18. The semiconductor device of claim 16, wherein the anti-nucleating layer is comprised of a member selected from the group consisting of GeO2, GeC, and GeCN.

19. The semiconductor device of claim 16, wherein the anti-nucleating layer is comprised of a member selected from the group consisting of SiO2, SiOF, SiCOH, SiC, and SiCN.

20. The semiconductor device of claim 16, wherein the anti-nucleating layer is comprised of amorphous carbon.
